(19) United States
(12) Patent Application Publication
(10) Pub. No.: US 2006/0161710 A1
(43) Pub. Date: Jul. 20, 2006

(54) Single board computer for industry personal computer

(75) Inventor: Chia Tsung Liu, Taipei (TW)

Correspondence Address: BACON & THOMAS, PLLC, 625 SLATERS LANE, FOURTH FLOOR, ALEXANDRIA, VA, 22314, US

(73) Assignee: Portwell Inc., Taipei (TW)

(21) Appl. No.: 11/288,109

(22) Filed: Nov. 29, 2005

(30) Foreign Application Priority Data
Jan. 18, 2005 (TW) 94101444

(51) Int. Cl. H05K 7/10; G06F 13/00

(52) U.S. Cl. 710/301

(57) ABSTRACT

A single board computer for an industry personal computer is disclosed. The single board computer comprises a CPU, a memory controller hub, and input/out zones, wherein at least one of the input/output zones is provided with a connector, the connector being dedicated for transporting a differential signal and connected with a wiring zone dedicated for differential signal on the single board computer, and being adapted to receive an interface card in compliance with a protocol for differential signal transport.

### FIELD OF THE INVENTION

This invention generally relates to a single board computer adapted to be installed in an industry Personal Computer (IPC), and, more particularly, to a single board computer provided with an input/output zone (hereinafter, called as I/O zone).

### DESCRIPTION OF THE RELATED ART

The industry PCs have been widely used to monitor and control a process in a plant and data transfer in a wireless communication station, to function as a server, etc. According to the architecture of industry PC, boards having various functions can be inserted in a chassis of the IPC. For example, one or more single board computers, one power supply board, one or more communication boards, etc. can be all installed in a single industry PC.

Recently, the single board computer for industry PC is designed in accordance with the ATCA (Advanced Telecom Computing Architecture) PICMG 3.0 or its subsidiary specifications. PICMG 3.0 defines a point to point connection for boards, and its subsidiary specifications define protocols over interconnections.

The subsidiary specifications of PICMG 3.0 include, for example, 3.1 Ethernet and Fiber channel Transport, 3.3 Star Fabric Transport, and 3.4 PCI Express and Advanced Switching Transport. In this content, a specification of PICMG 3.0 above includes PICMG 3.1, PICMG 3.2, etc. In other words, PICMG X.Y will be called “PICMG 3.0 above”, if X.Y is greater than 3.0 arithmetically.

Conventionally, a single board computer in compliance with a particular specification is only to provide a function compliant with the specification. Therefore, if a single board computer existing in an industry PC is required to meet a new specification different from the original one, the board will be replaced with another one compliant with the new specification, or configuration of wirings or a device on the board will be modified or replaced. For example, a single board computer in compliance with PICMG 3.1 can provided functions of PICMG 3.0 point to point communication and PICMG 3.1 interconnect protocol. A hardware or firmware providing such functions is installed on the board in a fixing manner such as welding. Therefore, if a single board computer compliant with PICMG 3.1 and existing inside an industry PC in a field is required to meet another specification such as PICMG 3.3, the board will be replaced with a new board in compliance with the required specification. Alternatively, the wirings or an electronic device on the board may be modified or replaced to meet the new requirements. Therefore, the cost for upgrading or reconfiguring the industry PC will be increased and time-consuming.

### SUMMARY OF THE INVENTION

In view of the above, this invention is to provide a single board computer for an industry computer, wherein interface cards compliant with different protocols can be easily replaced with each other so that cost can be reduced, and a flexible configuration is possible.

According to one aspect of the present invention, a single board computer for an industry personal computer comprises a CPU (central processing unit), a DRAM (dynamic random access memory), a memory controller hub, and input/out zones, and is characterized in that at least one of the input/output zones is provided with a connector, which is dedicated for transporting a differential signal and is connected with a wiring zone dedicated for differential signal on the single board computer, and the dedicated connector is adapted to receive an interface card in compliance with a protocol for differential signal transport.

According to another aspect of the present invention, a single board computer for an industry personal computer comprises a CPU, a DRAM, a memory controller hub, and one input/out zone, and is characterized in that the input/output zone is provided with a connector, which is dedicated for transporting a differential signal and is connected with a wiring zone dedicated for differential signal on the single board computer, and the dedicated connector is adapted to receive an interface card in compliance with a protocol for differential signal transport.

According to still another aspect of the present invention, an industry personal computer comprises a chassis having a plurality of slots and a single board computer inserted in one of the slots, and the single board computer includes a CPU, a DRAM, a memory controller hub, and input/out zones, and is characterized in that at least one of the input/output zones is provided with a connector, which is dedicated for a differential signal and is connected with a wiring zone dedicated for differential signal on the single board computer, and the dedicated connector is adapted to receive an interface card in compliance with a protocol for differential signal transport.

According to yet another aspect of the present invention, an industry personal computer comprises a chassis having a plurality of slots and a single board computer inserted in one of the slots, and the single board computer includes a CPU, a DRAM, a memory controller hub, and one input/out zone, and is characterized in that the input/output zones is provided with a connector, which is dedicated for a differential signal and is connected with a wiring zone dedicated for differential signal on the single board computer, and the dedicated connector is adapted to receive an interface card in compliance with a protocol for differential signal transport.

The protocol for differential signal transport comprises PICMG 3.1, PICMG3.2, PICMG3.3, PICMG3.4, etc.

According to PICMG 3.0 or above, the wiring zone for differential signal is Zone 2.

According to the present invention, the single board computer can be changed to comply with another specification different from the existing one simply by replacing an existing interface card with another one, without changing or replacing any circuit or components on the board. Therefore, if the board computer existing in an industry PC is required to meet another protocol, it is not necessary to replace the entire single board computer existing in an industry PC with another one in compliance with the required protocol.

### BRIEF DESCRIPTION OF THE DRAWINGS

FIG. 1 is a top view illustrating the arrangement of a single board computer according to one embodiment of the present invention;

FIG. 2 is a view showing the pin assignment for Zone 2 according to PICMG 3.0 or above; and

FIG. 3 is a block diagram showing interconnections between respective devices arranged on the single board computer shown in FIG. 1.

### DETAILED DESCRIPTION OF PREFERRED EMBODIMENT

The above and other objects, features, principles and advantages of the present invention will be more apparent form the detailed description given below with reference to the accompanying drawings.

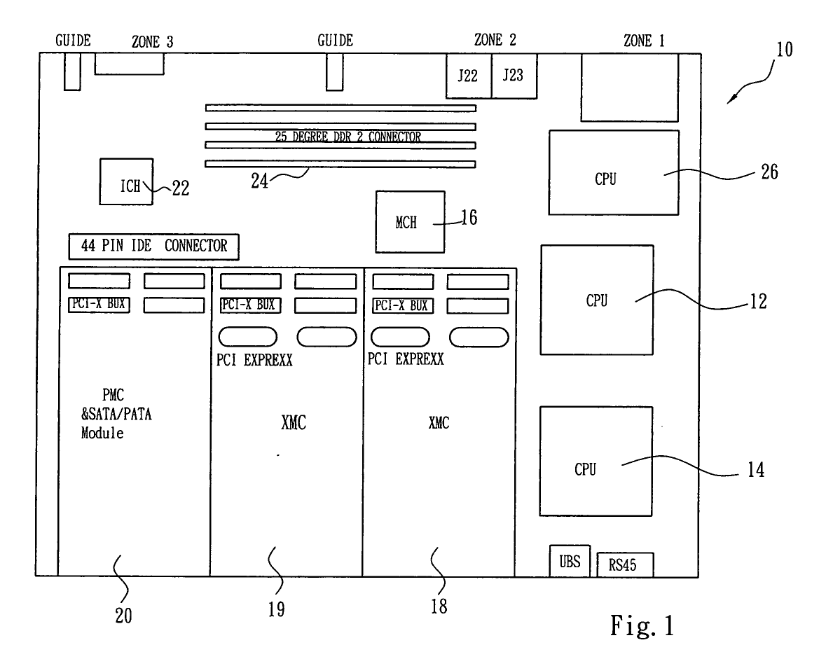

FIG. 1 is a top view illustrating the arrangement of the single board computer according to one embodiment of the present invention. For example, the single board computer 10 complies with ATCA PICMG 3.0 or above. As shown in FIG. 1, two CPUs 12 and 14, a memory hub controller (MCH) 16, input/output (I/O) zones 18, 19 compliant with XMC specification, and input/output (I/O) zones 20 compliant with PMC specification, an input/output controller hub (ICH) 22, a DRAM (dynamic random access memory) 24, and a power supply module 26 are arranged on the single board computer 10.

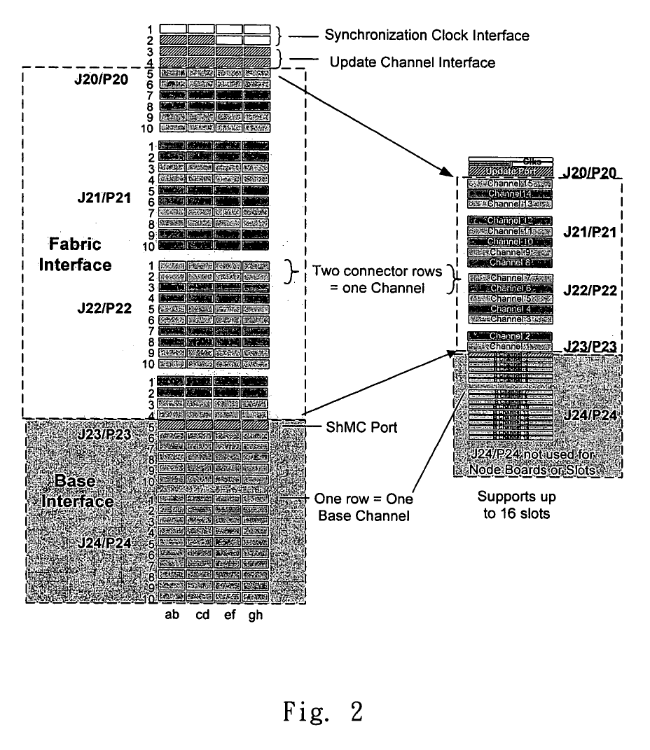

As shown in FIG. 1, according to PICMG 3.0 or above, the single board computer 10 is provided with three wiring zones, Zone 1, Zone 2, and Zone 3. Zone 1 is the wiring zone for power management, Zone 2 is the wiring zone for Fabric Interface, Base Interface, etc., and Zone 3 is the wiring zone for I/O interconnection on a rear panel. In particular, Zone 2 is mainly used for wirings, which transport differential signals. As shown in FIG. 2, for example, the single board computer 10 provides 15 communication channels for Fabric Interface. Each of the channels is composed of four ports and each port consists of two pairs of wires.

Slots for interface cards compliant with PCI-X BUS, PCI EXPRESS, or the like are provided in I/O areas 18, 19 compliant with XMC, as shown in FIG. 1. Such slots can receive an interface card compliant with these specifications to perform an input/output function. Furthermore, XMC is provided with a slot dedicated for the interface card compliant with PICMG 3.0 or above. One side of this slot is connected to Zone 2 to function as a communication channel for differential signal transport.

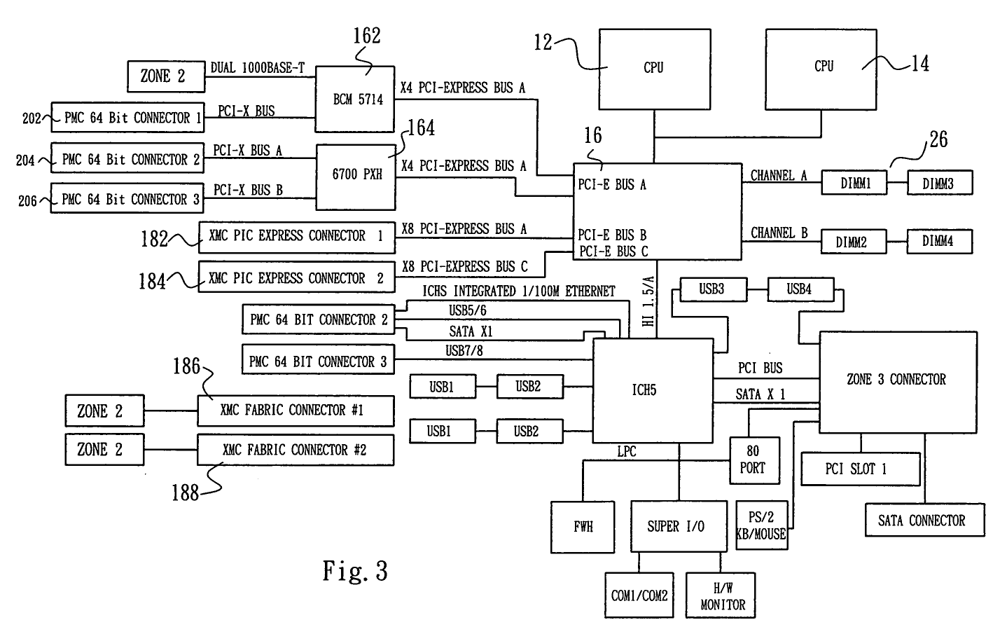

With reference to FIG. 3, the configuration and operation of the single board computer 10 according to one embodiment of the present invention will be further described. Two CPUs 12, 14 are connected with the MCH 16 to read/write data from/to DRAM 26 or transmit/receive instructions or commands to/from a peripheral device. MCH 16 provides three connection ports A, B, and C in compliance with PCI EXPRESS BUS specification. The connection port A is connected to a bridge 162 and a PCI-Express/PCI-X bridge 164. The other side of the bridge 162 is connected to the Zone 2 and to a 64-bit connector 22 on the PMC input/output area in order to establish a communication channel between the MCH 16 and the PMC input/output area.

As shown in FIG. 3, for performing communication with an external device, the bridge will convert data compliant with PCI EXPRESS BUS sent from the MCH 16 into a signal compliant with DUAL 1000 BASE-T, and vice versa. Alternatively, the bridge will convert data compliant with PCI EXPRESS BUS sent from the MCH 16 into a signal compliant with PCI-X BUS, and vice versa. The other two connection ports B and C of the MCH 16 are connected to two connectors 182, 184, which are compliant with PCI EXPRESS specification and provided on two XMC input/output cards 18, 19, respectively, thereby to establish a communication channel.

It is noted that as illustrated in FIG. 3, the XMC input/output cards 18, 19 shown in FIG. 1 are provided with FABRIC INTERFACE connectors 186, 188, which can receive a FABRIC INTERFACE card and be connected to the Zone 2 of the single board computer 10. Zone 2, for example, comprises pins J22/P22, J23/P23, etc. According to one embodiment of the present invention, since the XMC input/output cards 18, 19 are provided with slots dedicated for the FABRIC interface card, various FABRIC cards compliant with different standards can be easily exchanged with each other, without modifying or changing any wiring or circuit on the single board computer 10. For example, if the single board computer 10 having the FABRIC interface card compliant with PICMG 3.1 is required to provide a communication function in compliance with PICMG 3.3 standard, the user or the operator can remove the PICMG 3.1 FABRIC interface card from XMC 18 or 19 and then insert a PICMG 3.3 interface card into the slot. Therefore, the single board computer can be easily changed to provide the PICMG 3.3 communication function. For convenience of explanation, although the connectors 186, 188 are described to receive the FABRIC interface card, but it should be understood that the connectors 186, 188 are not limited to this but compatible with any interface cards adapted to transport a differential signal. For example, according to a high-speed storage device standard such as SATA (Serial AT Attachment) and SAS (Serial Attached SCSI), since the storage device performs data communication based on a serial differential signal, the connectors 186 or 188can allow any interface cards in compliant with SATA or SAS standards to be inserted therein for such data communication.

According to the present invention, an interface card or a communication module existing on a single board computer can be easily and rapidly replaced with another one compliant with a communication standard different from the existing one, without modifying or changing any circuit or elements on the single board computer and exchanging the single board computer with another one.

While the invention has been described in conjunction with the detailed description of above embodiment, various variations and modifications can be made without departing from the spirit or the scope of this invention defined by the appended claims.

1. A single board computer for an industry personal computer comprising a CPU, a memory controller hub, and input/out zones, the single board computer being characterized in that: at least one of the input/output zones is provided with a connector, the connector being dedicated for transporting a differential signal and connected with a wiring zone dedicated for differential signal on the single board computer, and being adapted to receive an interface card in compliance with a protocol for differential signal transport.

2. The single board computer according to claim 1, wherein the protocol for differential signal transport comprises SATA, SAS, PICMG 3.1, PICMG3.2, PICMG3.3, PICMG3.4 and above specifications.

3. The single board computer according to claim 1, wherein the wiring zone dedicated for differential signal is a wiring area in compliance with ZONE 2 defined by PICMG 3.0 or above.

4. A single board computer for an industry personal computer comprising a CPU, a DRAM, a memory controller hub, and one input/out zone, and the single board computer being characterized in that the input/output zone is provided with a connector, which is dedicated for transporting a differential signal and is connected with a wiring zone dedicated for differential signal on the single board computer, and the dedicated connector is adapted to receive an interface card in compliance with a protocol for differential signal transport.

5. The single board computer according to claim 4, wherein the protocol for differential signal transport comprises SATA, SAS, PICMG 3.1, PICMG3.2, PICMG3.3, PICMG3.4 and above specifications.

6. The single board computer according to claim 4, wherein the wiring zone dedicated for differential signal is a wiring area in compliance with ZONE 2 defined by PICMG 3.0 or above.

7. An industry personal computer comprising a chassis having a plurality of slots and at least one single board computer inserted in one of the slots, the single board computer including a CPU, a DRAM, a memory controller hub, and input/out zones, and being characterized in that at least one of the input/output zones is provided with a connector, which is dedicated for a differential signal and is connected with a wiring zone dedicated for differential signal on the single board computer, and the dedicated connector is adapted to receive an interface card in compliance with a protocol for differential signal transport.

8. The industry computer according to claim 7, wherein the protocol for differential signal transport comprises SATA, SAS, PICMG 3.1, PICMG3.2, PICMG3.3, PICMG3.4 and above specifications.

9. The industry computer according to claim 7, wherein the wiring zone dedicated for differential signal is a wiring area in compliance with ZONE 2 defined by PICMG 3.0 or above.

10. An industry personal computer comprising a chassis having a plurality of slots and at least one single board computer inserted in one of the slots, the single board computer including a CPU, a DRAM, a memory controller hub, and one input/out zone, and being characterized in that the input/output zone is provided with a connector, which is dedicated for a differential signal and is connected with a wiring zone dedicated for differential signal on the single board computer, and the dedicated connector is adapted to receive an interface card in compliance with a protocol for differential signal transport.

11. The industry computer according to claim 10, wherein the protocol for differential signal transport comprises SATA, SAS, PICMG 3.1, PICMG3.2, PICMG3.3, PICMG3.4 and above specifications.

12. The industry computer according to claim 10, wherein the wiring zone dedicated for differential signal is a wiring area in compliance with ZONE 2 defined by PICMG 3.0 or above.
